(19) United States
(12) Patent Application Publication
(10) Pub. No.: US 2023/0197530 A1
(43) Pub. Date: Jun. 22, 2023

(54) SEMICONDUCTOR DEVICE HAVING REDUCED CONTACT RESISTANCE

(71) Applicant: INTERNATIONAL BUSINESS MACHINES CORPORATION, Armonk, NY (US)

(72) Inventors: Ruilong Xie, Niskayuna, NY (US); Andrew M. Greene, Slingerlands, NY (US); Veeraraghavan S. Basker, Schenectady, NY (US); Jingyun Zhang, Albany, NY (US); Alexander Reznicek, Troy, NY (US)

(21) Appl. No.: 17/554,765

(22) Filed: Dec. 17, 2021

(51) Int. Cl. H01L 21/84; H01L 27/12

(52) U.S. Cl. CPC H01L 21/845; H01L 27/1207; H01L 27/1211

(57) ABSTRACT

A semiconductor device is provided. The semiconductor device includes a top field effect device over a bottom field effect device, and a bottom contact electrically connecting a bottom source/drain of the bottom field effect device to a first buried power rail. The semiconductor device further includes a bottom contact cap on the bottom contact, and a trench liner on opposite sides of the bottom contact cap and the bottom contact.

### BACKGROUND

The present invention generally relates to reduced source/drain contact resistance, and more particularly to stacked field effect transistors having an optimized bottom source/drain contact resistance.

A Field Effect Transistor (FET) typically has a source, a channel, and a drain, where current flows from the source to the drain, and a gate that controls the flow of current through the device channel. Field Effect Transistors (FETs) can have a variety of different structures, for example, FETs have been fabricated with the source, channel, and drain formed in the substrate material itself, where the current flows horizontally (i.e., in the plane of the substrate), and FinFETs have been formed with the channel extending outward from the substrate, but where the current also flows from a source to a drain. Depending on the doping of the source and drain, an n-FET or a p-FET can be formed. Two FETs also can be coupled to form a stacked metal oxide semiconductor (CMOS) device, where a p-channel MOSFET and n-channel MOSFET are coupled together.

### SUMMARY

In accordance with an embodiment of the present invention, a semiconductor device is provided. The semiconductor device includes a top field effect device over a bottom field effect device, and a bottom contact electrically connecting a bottom source/drain of the bottom field effect device to a first buried power rail. The semiconductor device further includes a bottom contact cap on the bottom contact, and a trench liner on opposite sides of the bottom contact cap and the bottom contact.

In accordance with another embodiment of the present invention, a semiconductor device is provided. The semiconductor device includes a top field effect device having a top source/drain over a bottom field effect device having a bottom source/drain, and a bottom contact in electrical contact with the bottom source/drain of the bottom field effect device. The semiconductor device further includes a bottom contact cap on the bottom contact, wherein a portion of the bottom contact and a portion of the bottom contact cap separate the bottom source/drain from the top source/drain.

In accordance with yet another embodiment of the present invention, a method of fabricating a semiconductor device is provided. The method includes forming a bottom source/drain on a bottom fin region, and implanting and pre-amorphization the bottom source/drain with a dopant. The method further includes forming a bottom contact on the bottom source/drain, and forming a bottom contact cap on the bottom contact. The method further includes forming a top source/drain on the bottom contact cap and a top fin region.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 illustrates perpendicular cross-sectional side views showing a pair of fins on a substrate and a plurality of dummy gate structures across the fins, in accordance with an embodiment of the present invention;

FIG. 2 illustrates perpendicular cross-sectional side views showing a sacrificial pinch-off layer formed between the pair of fins and on a shallow trench isolation region, in accordance with an embodiment of the present invention;

FIG. 3 illustrates perpendicular cross-sectional side views showing sidewall spacers formed on the pair of fins and on the dummy gate structures, in accordance with an embodiment of the present invention;

FIG. 4 illustrates perpendicular cross-sectional side views showing recessing of the fins between the sidewall spacers and removal of the sacrificial pinch-off layer, in accordance with an embodiment of the present invention;

FIG. 5 illustrates perpendicular cross-sectional side views showing formation of source/drain regions in recess cavities, in accordance with an embodiment of the present invention;

FIG. 6 illustrates perpendicular cross-sectional side views showing formation of a protective cover layer on the source/drain regions in recess cavities, in accordance with an embodiment of the present invention;

FIG. 7 illustrates perpendicular cross-sectional side views showing formation of top spacers on the sidewall spacers, in accordance with an embodiment of the present invention;

FIG. 8 illustrates perpendicular cross-sectional side views showing removal of the protective layer from the source/drain regions, in accordance with an embodiment of the present invention;

FIG. 9 illustrates perpendicular cross-sectional side views showing sidewall spacer pulldown and source/drain region recessing, in accordance with an embodiment of the present invention;

FIG. 10 illustrates perpendicular cross-sectional side views showing formation of an interlayer dielectric (ILD) layer on bottom source/drains, and removal of the top spacers and dummy gate hardmasks, in accordance with an embodiment of the present invention;

FIG. 11 illustrates perpendicular cross-sectional side views showing removal of the dummy gate fill from between the sidewall spacers, in accordance with an embodiment of the present invention;

FIG. 12 illustrates perpendicular cross-sectional side views showing formation of a replacement gate and gate dielectric cap between the sidewall spacers, in accordance with an embodiment of the present invention;

FIG. 13 illustrates perpendicular cross-sectional side views showing formation of a bottom contact trench in the ILD layer, in accordance with an embodiment of the present invention;

FIG. 14 illustrates perpendicular cross-sectional side views showing formation of a trench liner in the bottom contact trench, in accordance with an embodiment of the present invention;

FIG. 15 illustrates perpendicular cross-sectional side views showing bottom source/drain implantation and pre-amorphization, in accordance with an embodiment of the present invention;

FIG. 16 illustrates perpendicular cross-sectional side views showing formation of a bottom contact in the bottom contact trench, in accordance with an embodiment of the present invention;

FIG. 17 illustrates perpendicular cross-sectional side views showing formation of a bottom contact cap in the bottom contact trench on the bottom contact, and a top source/drain formed on the top fin region and bottom contact cap, in accordance with an embodiment of the present invention;

FIG. 18 illustrates perpendicular cross-sectional side views showing formation of a top source/drain contact between the top source/drain and a second buried power rail, and a signal contact in a cover layer, in accordance with an embodiment of the present invention; and

FIG. 19 illustrates perpendicular cross-sectional side views showing formation of a bottom source/drain contact and a top source/drain contact in a cover layer, in accordance with an embodiment of the present invention.

### DETAILED DESCRIPTION

Embodiments of the present invention provide stacked field effect transistors having an optimized bottom source/drain contact resistance. Approximately a 1×10⁻⁹ Ω/cm² contact resistance can be achieved with a source/drain pre-amorphization, dopant implant, and pre-clean before metallization. The bottom source/drain contact resistance can be the bottleneck for device performance improvement.

Embodiments of the present invention provide stacked field effect transistor (FET) devices with an n-type FET on a p-type FET, or a p-type FET on an n-type FET, or an n-type FET on an n-type FET, or a p-type FET on a p-type FET, to form a stacked FET. A source/drain of the bottom device can be attached to a first buried power rail and a source/drain of the top device can be formed to a second power rail. The bottom source/drain contact to the first buried power rail can be electrically separated from the substrate by a portion of a spacer.

Embodiments of the present invention provide a method of fabricating stacked field effect transistor (FET) devices with an optimized bottom source/drain contact resistance.

Embodiments of the present invention provide two fin PFET device over two fin NFET device on a silicon-on-insulator substrate for illustration purposes, where the invention applies to any kinds of devices over any kinds of substrate (e.g. nanosheet, nanowire, over bulk substrate, etc.).

Exemplary applications/uses to which the present invention can be applied include, but are not limited to: microprocessors, microcontrollers, memory chips (including CMOS BIOS), and other digital logic circuits. It can be also used for analog circuits such as image sensors (CMOS sensors), data converters, RF circuits (RF CMOS), and highly integrated transceivers for many types of communication.

It is to be understood that aspects of the present invention will be described in terms of a given illustrative architecture; however, other architectures, structures, substrate materials and process features and steps can be varied within the scope of aspects of the present invention.

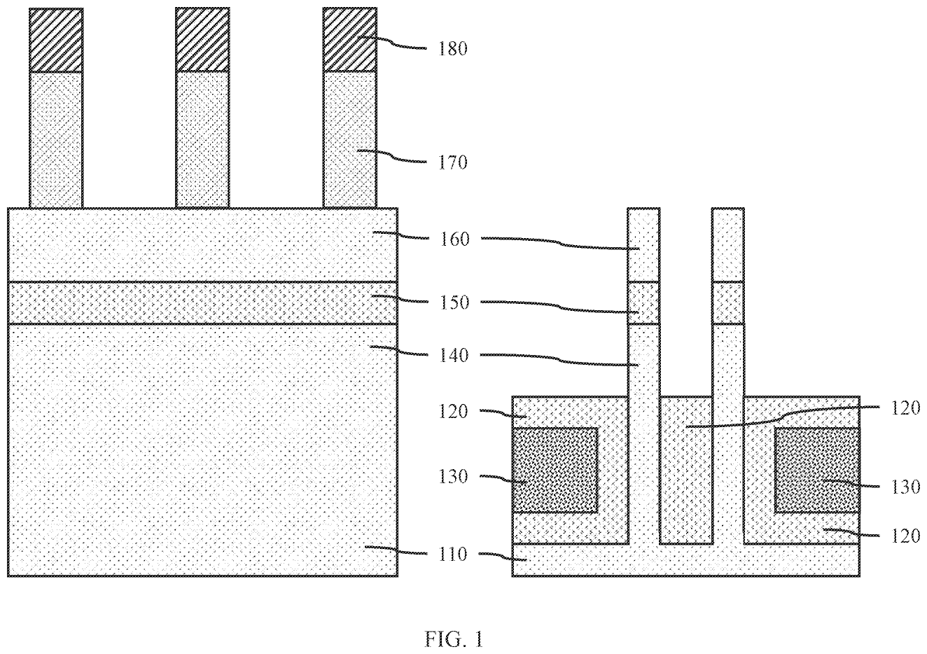

Referring now to the drawings in which like numerals represent the same or similar elements and initially to FIG. 1, FIG. 1 illustrates perpendicular cross-sectional side views showing a pair of fins on a substrate and a plurality of dummy gate structures across the fins, in accordance with an embodiment of the present invention.

In one or more embodiments, a plurality of fins can be formed on a substrate 110, where each fin can include an insulating layer 150 separating a top fin region 160 from a bottom fin region 140. A shallow trench isolation region 120 can be on the substrate 110 and adjacent to a portion of each of the bottom fin regions 140. Shallow trench isolation regions can be adjacent to a portion of the bottom fin regions 140. A portion of the shallow trench isolation regions 120 can be between two adjacent bottom fin regions 140.

In one or more embodiments, a buried power rail 130 can be formed in each shallow trench isolation region 120, where a buried power rail 130 can be formed between different stacked FET cells, where 1 cell of stacked FET is shown.

In one or more embodiments, a plurality of dummy gate structures, including a dummy gate fill 170 and a dummy gate hardmask 180, can be formed across the fins, where a portion of the dummy gate fill 170 can be over the exposed fin 160, 150, 140.

In various embodiments, the substrate can be a bulk substrate or a silicon-on-insulator (SOI) substrate, where the insulating layer 150 could be formed from a buried oxide (BOX) layer of the SOI substrate.

In one or more embodiments, the substrate 110 can be a semiconductor substrate, where the substrate 110 can be a type IV semiconductor, for example, silicon (Si) or germanium (Ge), or a type IV-IV compound semiconductor, for example, silicon-germanium (SiGe) or silicon carbide (SiC), a type III-V compound semiconductor, for example, gallium arsenide (GaAs), gallium nitride (GaN), or indium phosphide (InP). The top fin region(s) 160 and bottom fin region(s) 140 can be formed from a SOI substrate 110 by masking and etching.

In one or more embodiments, shallow trench isolation (STI) regions 120 can be formed in the substrate 110, where the STI regions 120 can be formed by lithographic processes, etching trenches, and deposition of an electrically insulating dielectric material in the trenches.

In various embodiments, a shallow trench isolation (STI) regions 120 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

In various embodiments, the buried power rail 130 can be a metal, including, but not limited to, copper (Cu), tungsten (W), cobalt (Co), ruthenium (Ru), and combinations thereof. Note that a thin adhesion metal layer, such as TiN or TaN is deposited prior to the BPR metal deposition. After metal deposition, the metals are planarized and recessed. Additional STI dielectric can be formed over the recessed BPR.

In various embodiments, the insulating layer 150 can be an electrically insulating dielectric material, including, but not limited to, silicon oxide (SiO₂), silicon nitride (SiN), silicon oxynitride (SiON) silicon oxy carbide (SiOC), silicon oxy carbonitride (SiOCN), silicon boro carbonitride (SiBCN), and combinations thereof. The insulating layer 150 can be the same material as the shallow trench isolation region 120 or a different material. If the starting wafer is a SOI wafer, the insulating layer 150 is the initial BOX layer.

In various embodiments, dummy gate fill 170 can be a selectively removable material, including, but not limited to, amorphous silicon (a-Si), amorphous germanium (a-Ge), amorphous carbon (a-C), and combinations thereof. The dummy gate hardmask 180 can be a dielectric hardmask material, including, but not limited to, silicon oxide (SiO), silicon nitride (SiN), silicon oxynitride (SiON), silicon boronitride (SiBN), titanium nitride (TiN), and combinations thereof.

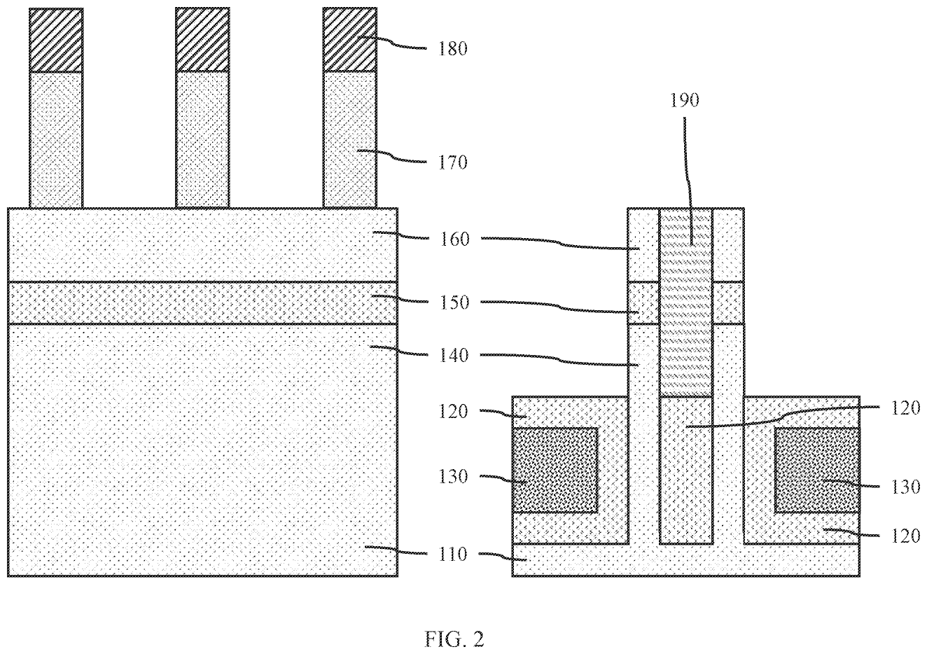

FIG. 2 illustrates perpendicular cross-sectional side views showing a sacrificial pinch-off layer formed between the pair of fins and on a shallow trench isolation region, in accordance with an embodiment of the present invention.

In one or more embodiments, a sacrificial pinch-off layer 190 can be formed between the pair of fins, where the sacrificial pinch-off layer 190 can fill in the space between the adjacent insulating layers 150, top fin regions 160, and bottom fin regions 140. The sacrificial pinch-off layer 190 can be formed by a conformal deposition, for example, atomic layer deposition (ALD) or plasma enhanced ALD (PEALD), and a selective isotropic etch-back from other exposed surfaces.

In one or more embodiments, the sacrificial pinch-off layer 190 can be a dielectric material, including, but not limited to, titanium oxide (TiO), aluminum oxide (AlO), and combinations thereof, where the sacrificial pinch-off layer 190 can be selectively removed relative to the insulating layer 150 and shallow trench isolation region(s) 120.

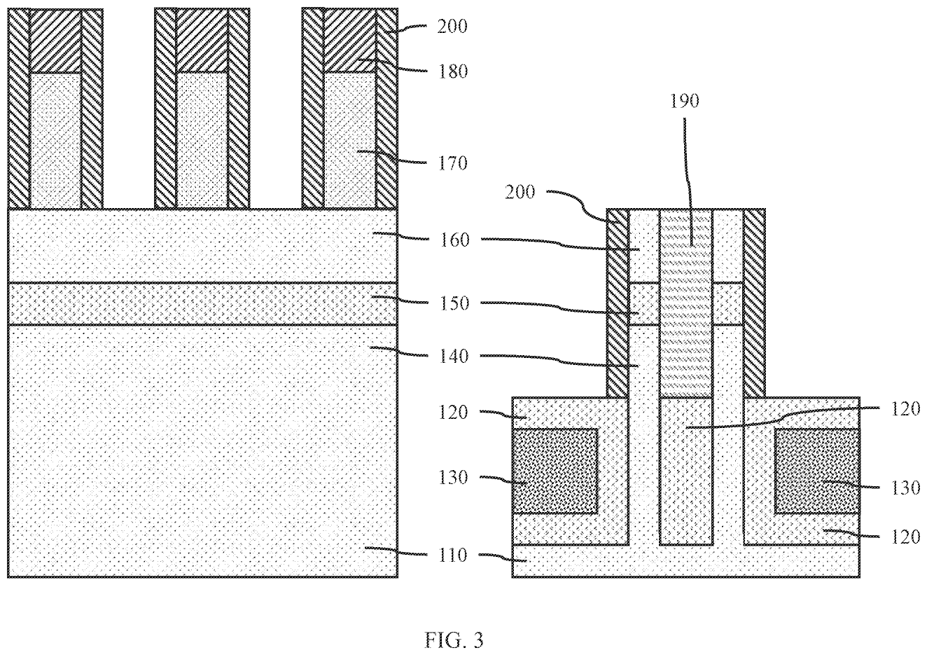

FIG. 3 illustrates perpendicular cross-sectional side views showing sidewall spacers formed on the pair of fins and on the dummy gate structures, in accordance with an embodiment of the present invention.

In one or more embodiments, sidewall spacers 200 can be formed on the plurality of fins and on the dummy gate structures, where the sidewall spacers 200 can be formed on the insulating layer 150, top fin region 160, bottom fin region 140, dummy gate fill 170, and a dummy gate hardmask 180, by conformally depositing the sidewall spacer material on the exposed surfaces and removing portions from the horizontal surfaces using a selective directional etch, for example, a reactive ion etch (RIE). A portion of the sidewall spacers 200 can be on the top surface of the top fin region 160 and on the shallow trench isolation regions 120. The sacrificial pinch-off layer 190 can block the sidewall spacers 200 from forming between the adjacent fins.

In various embodiments, the sidewall spacers 200 can be a dielectric material, including, but not limited to, silicon oxide (SiO), silicon nitride (SiN), silicon oxynitride (SiON), silicon carbide (SiC), silicon oxycarbide (SiOC), silicon carbonitride (SiCN), silicon boro carbonitride (SiBCN), silicon oxy carbonitride (SiOCN), and combinations thereof.

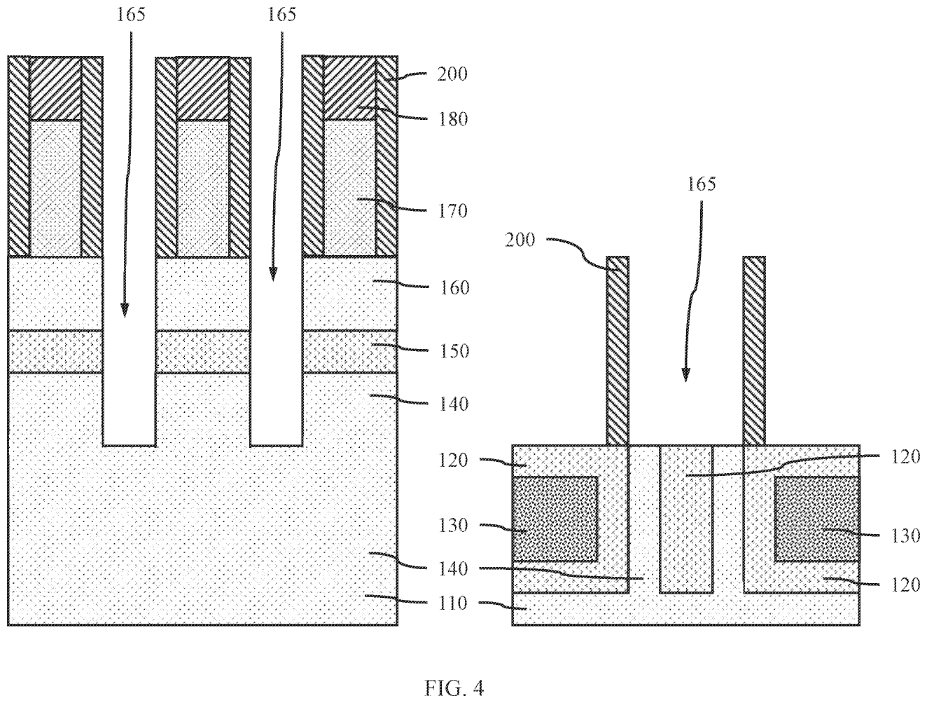

FIG. 4 illustrates perpendicular cross-sectional side views showing recessing of the fins between the sidewall spacers and removal of the sacrificial pinch-off layer, in accordance with an embodiment of the present invention.

In one or more embodiments, the sacrificial pinch-off layer 190 can be removed using a selective isotropic etch.

In one or more embodiments, the fins between the sidewall spacers 200 can be recessed using a selective, directional etch (e.g., RIE), where portions of the top fin regions 160, insulating layers 150, and bottom fin regions 140 can be removed down to the top surface of the shallow trench isolation regions 120. Removal of the portions of the top fin regions 160, insulating layers 150, and bottom fin regions 140 can form recess cavities 165 for forming source/drain regions.

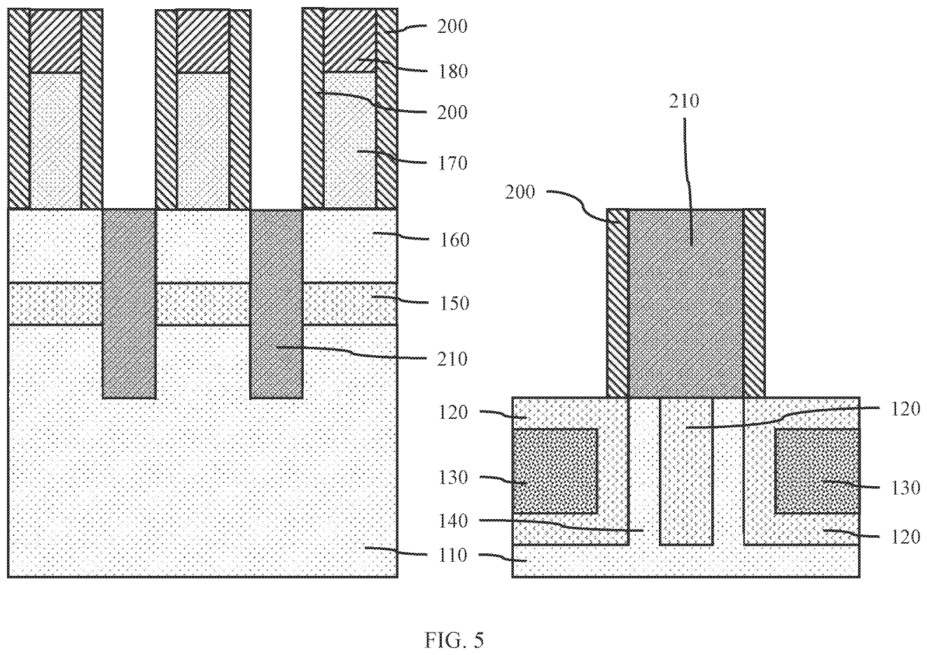

FIG. 5 illustrates perpendicular cross-sectional side views showing formation of source/drain regions in recess cavities, in accordance with an embodiment of the present invention.

In one or more embodiments, source/drain regions 210 can be formed in the recess cavities 165, where the source/drain regions 210 can be formed by epitaxial growth from the top surfaces of the bottom fin regions 140 and sidewall surfaces of the bottom fin regions 140 and top fin regions 160. The top surface of the source/drain regions 210 can be coplanar with the top surface of the top fin regions 160.

In various embodiments, the source/drain regions 210 can be doped with an n-type dopant to fabricate an n-type FET (NFET) or a p-type dopant to fabricate a p-type FET (PFET). The dopant can be added in situ while growing the source/drain regions 210.

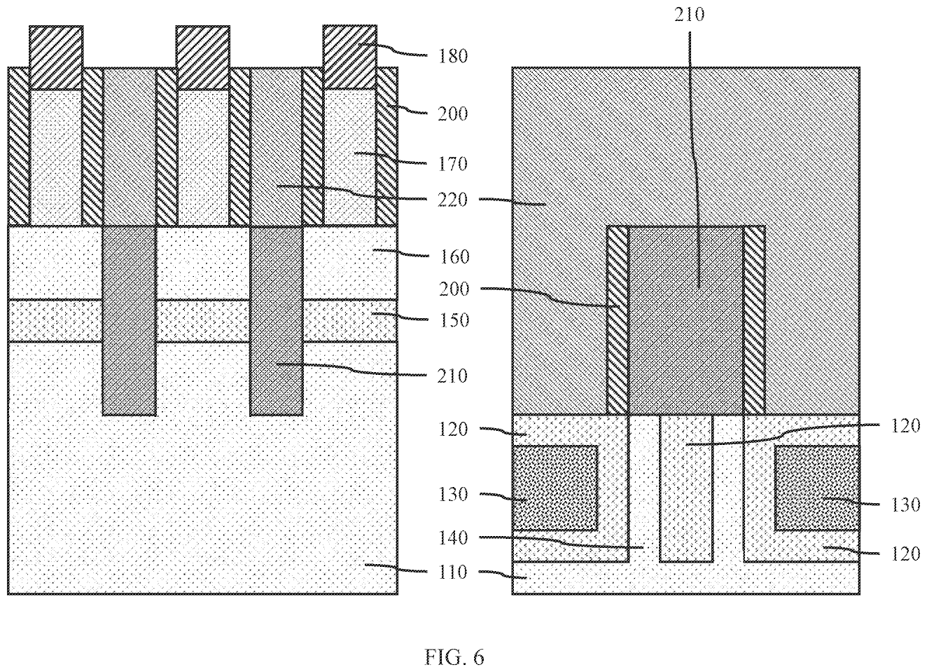

FIG. 6 illustrates perpendicular cross-sectional side views showing formation of a protective cover layer on the source/drain regions in recess cavities, in accordance with an embodiment of the present invention.

In one or more embodiments, a protective cover layer 220 can be formed on the source/drain regions 210 and the sidewall spacers 200, where the protective cover layer 220 can be formed by a blanket deposition, for example, a spin-on coating of an OPL. The protective cover layer 220 can be etched back to expose an upper portion of the sidewall spacers 200 and the top surface of the dummy gate hardmask 180.

In various embodiments, the protective cover layer 220 can be an organic planarization layer (OPL) or organosilicate glass.

In various embodiments, the exposed upper portion of the sidewall spacers 200 can be removed using a selective etch, such that the top surface of the sidewall spacers 200 are approximately coplanar with the top surface of the protective cover layer 220.

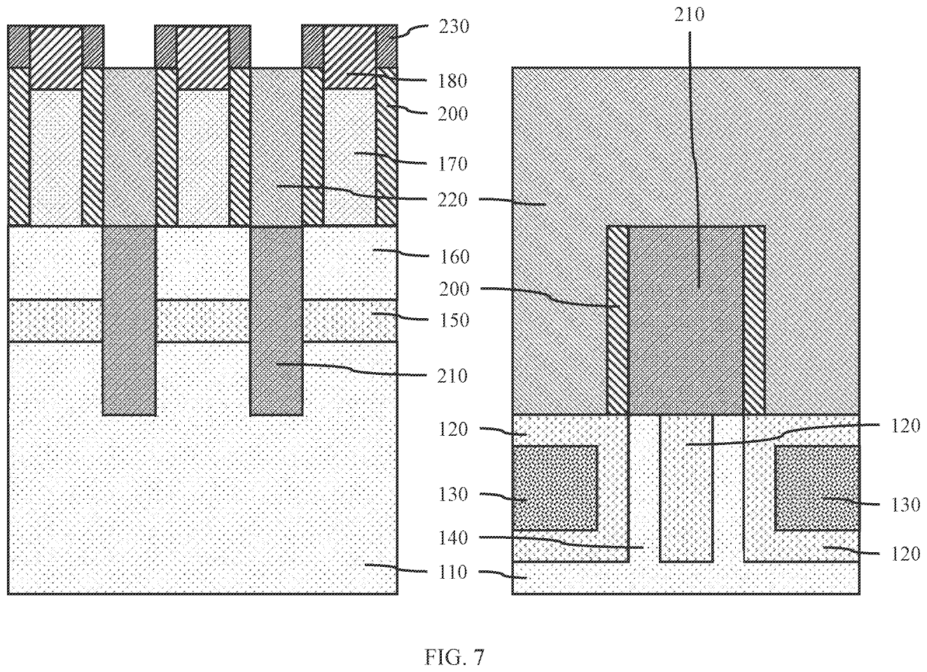

FIG. 7 illustrates perpendicular cross-sectional side views showing formation of top spacers on the sidewall spacers, in accordance with an embodiment of the present invention.

In one or more embodiments, top spacers 230 can be formed on the sidewall spacers 200 and the dummy gate hardmask 180, where the top spacers 230 can be formed by conformally depositing a top spacer layer and removing portions of the layer from the horizontal surfaces using a selective directional etch (e.g., RIE).

In various embodiments, the top spacers 230 can be carbon doped silicon oxide (SiCO).

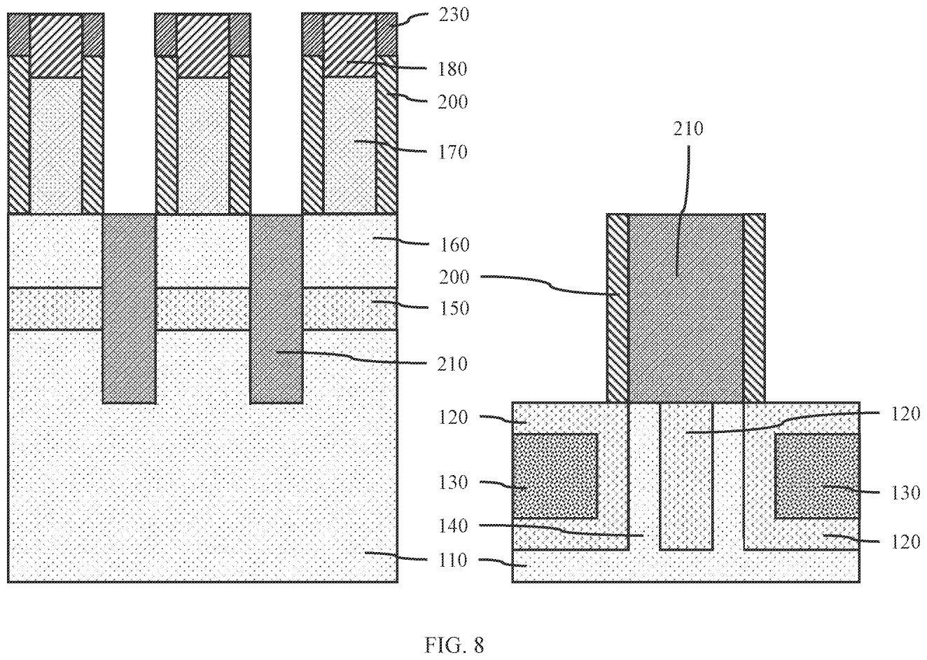

FIG. 8 illustrates perpendicular cross-sectional side views showing removal of the protective layer from the source/drain regions, in accordance with an embodiment of the present invention.

In one or more embodiments, the protective layer 220 can be removed from the source/drain regions 210, where the protective layer 220 can be removed using a selective isotropic etch. In case where the protective layer 220 is an OPL, the selective etch process can be N₂/H₂ ash. Removal of the protective layer 220 can expose the sidewall spacers 200 and top surface of the source/drain regions 210, as well as the shallow trench isolation regions 120.

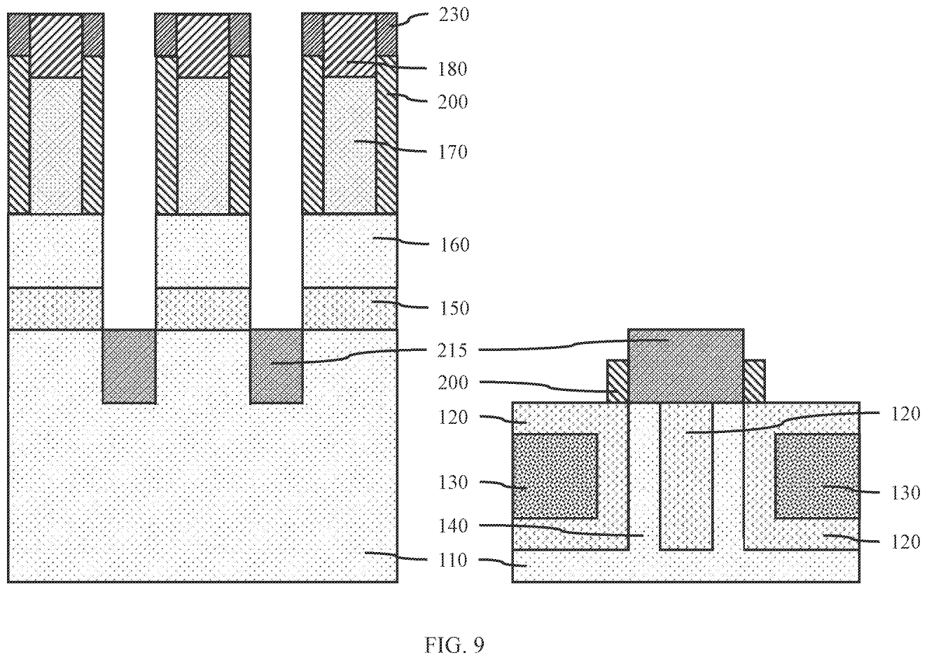

FIG. 9 illustrates perpendicular cross-sectional side views showing sidewall spacer pulldown and source/drain region recessing, in accordance with an embodiment of the present invention.

In one or more embodiments, an upper portion of the source/drain regions 210 can be removed to recess the source/drain regions 210 below the top surface of the insulating layer 150. In various embodiments, the upper portion of the source/drain regions 210 can be removed using a selective isotropic etch to form bottom source/drains 215. In various embodiments, the top surface of the bottom source/drains 215 can be approximately coplanar with the bottom surface of the insulating layer 150.

In one or more embodiments, the sidewall spacers 200 can be etched back between the dummy gate structures, where the height of the sidewall spacers 200 is less than the height of the bottom source/drains 215 between the bottom fin regions 140. The sidewall spacers 200 can be etched back using a selective, directional etch (e.g., RIE). The top spacers 230 can protect the portions of the sidewall spacers 200 on the dummy gate structures during the sidewall spacer etch-back. The remaining portion of the sidewall spacers 200 on the bottom source/drains 215 can provide electrical insulation, so a contact to the buried power rail 130 does not short to the substrate 110.

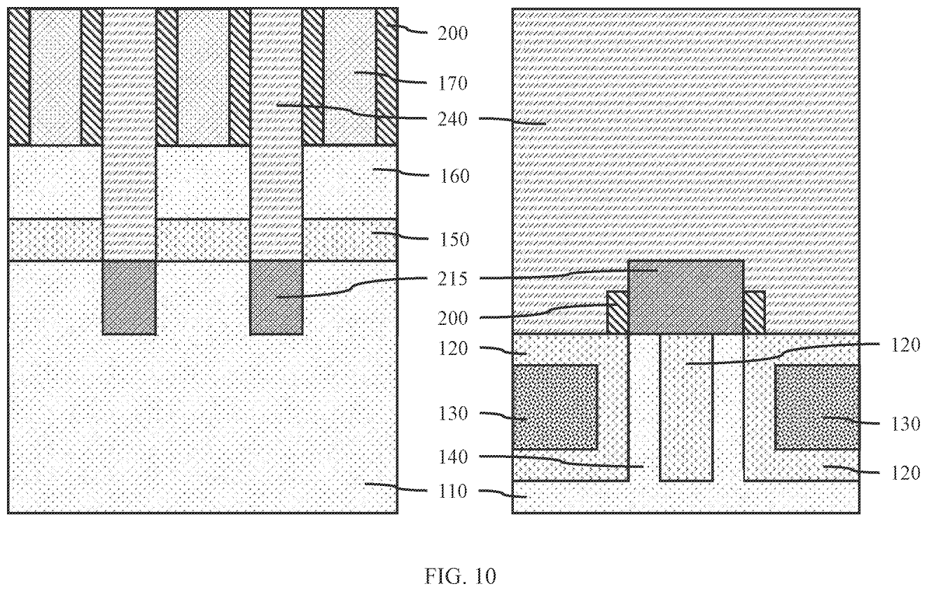

FIG. 10 illustrates perpendicular cross-sectional side views showing formation of an interlayer dielectric (ILD) layer on bottom source/drains, and removal of the top spacers and dummy gate hardmasks, in accordance with an embodiment of the present invention.

In one or more embodiments, an interlayer dielectric (ILD) layer 240 can be formed on bottom source/drains 215, sidewall spacers 200, and shallow trench isolation regions 120. The interlayer dielectric (ILD) layer 240 can fill in the spaces between the dummy gate structures, insulating layer 150, and top fin regions 160.

In various embodiments, the interlayer dielectric (ILD) layer 240 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof. The interlayer dielectric (ILD) layer 240 can be a different dielectric material from the shallow trench isolation regions 120 to allow selective removal.

In one or more embodiments, the top spacers 230 and dummy gate hardmasks 180 can be removed, where the top spacers 230 and dummy gate hardmasks 180 can be removed by chemical-mechanical polishing (CMP). Removal of the top spacers 230 and dummy gate hardmasks 180 can expose the dummy gate fill 170. An upper portion of the sidewall spacers 200 can also be removed, where the top surface of the sidewall spacers 200 can be approximately coplanar with the top surface of the dummy gate fill 170 and ILD layer 240.

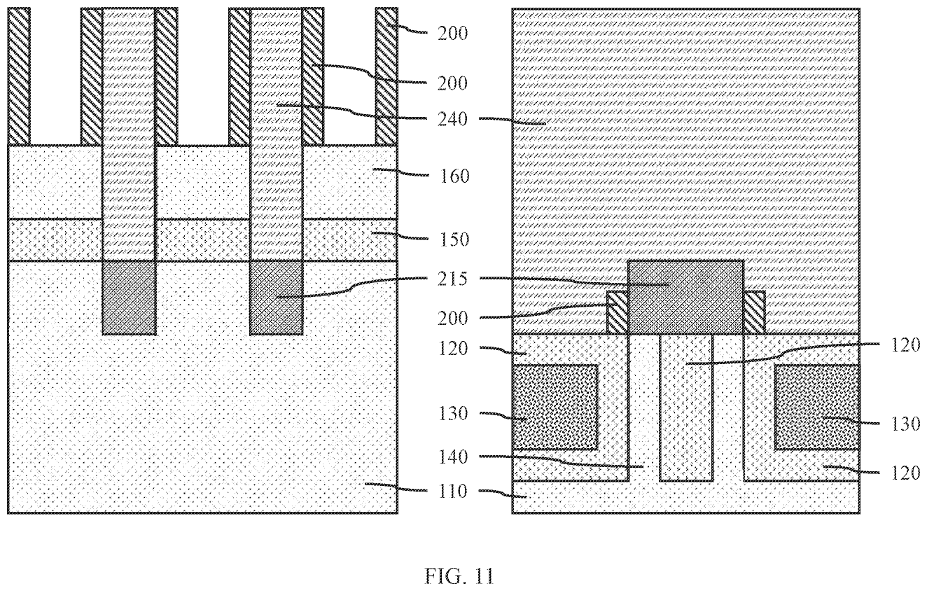

FIG. 11 illustrates perpendicular cross-sectional side views showing removal of the dummy gate fill from between the sidewall spacers, in accordance with an embodiment of the present invention.

In one or more embodiments, the dummy gate fill 170 can be removed from between the sidewall spacers 200, where the dummy gate fill 170 can be removed using a selective isotropic etch. Removal of the dummy gate fill 170 can expose the underlying portions of the top and bottom fin regions 160, 140.

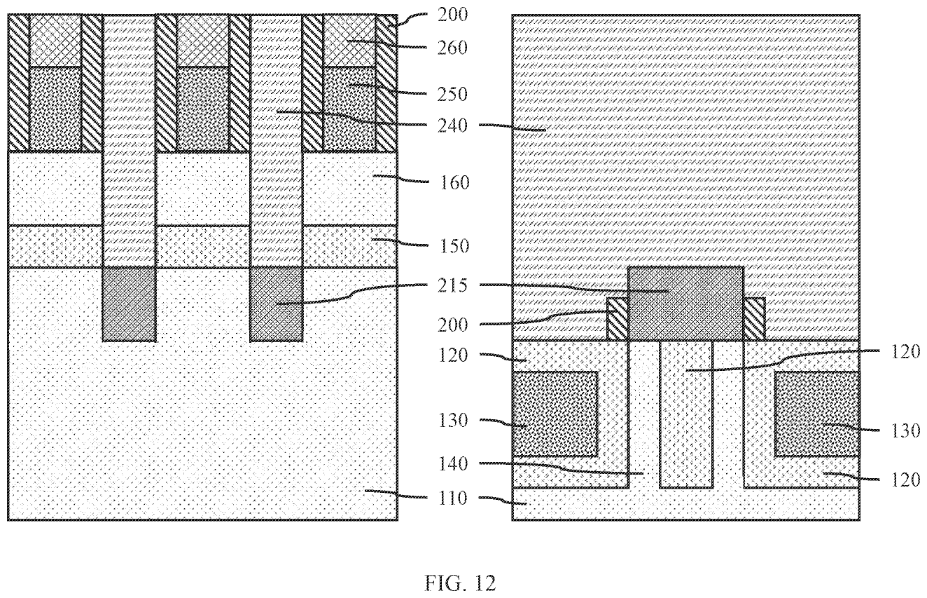

FIG. 12 illustrates perpendicular cross-sectional side views showing formation of a replacement gate and gate dielectric cap between the sidewall spacers, in accordance with an embodiment of the present invention.

In one or more embodiments, a replacement gate 250 and gate dielectric cap 260 can be formed on the top and bottom fin regions 160, 140. The replacement gate 250 can be formed by a conformal deposition of a gate dielectric materials, such as HfO₂, ZrO₂, HfLaOx, HfAlOx, etc, and metal gates over the top and bottom fin regions 160, 140 between the sidewall spacers 200. Optionally, the replacement gate 250 can be recessed, and a gate dielectric cap 260 can be formed on the replacement gate 250, where the gate dielectric cap 260 can be formed by a dielectric deposition and etch-back or CMP.

In various embodiments, the gate metal layer can be, for example, tungsten (W), cobalt (Co), ruthenium (Ru), and combinations thereof, and the work function metal layer can be a metal compound, for example, tantalum nitride (TaN), titanium nitride (TiN), tantalum carbide (TaC), titanium carbide (TiC), titanium aluminum carbide (TiAlC), and combinations thereof.

In various embodiments, the gate dielectric cap 260 can be an electrically insulating dielectric material, including, but not limited to, silicon oxide (SiO₂), silicon nitride (SiN), silicon oxynitride (SiON) silicon oxy carbide (SiOC), silicon oxy carbonitride (SiOCN), silicon boro carbonitride (SiBCN), and combinations thereof.

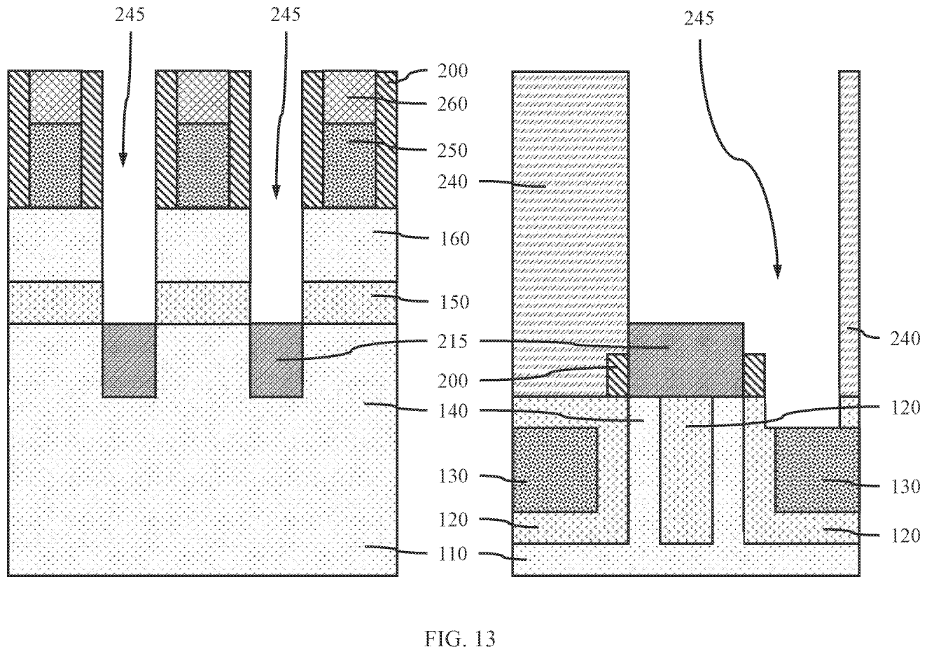

FIG. 13 illustrates perpendicular cross-sectional side views showing formation of a bottom contact trench in the ILD layer, in accordance with an embodiment of the present invention.

In one or more embodiments, a bottom contact trench 245 can be formed in the ILD layer 240, where a portion of the ILD layer 240 can be removed using a lithographic process and selective, directional etching (e.g., RIE) to expose the bottom source/drains 215 and sidewall spacer 200. Selective, directional etching (e.g., RIE) to remove a portion of the shallow trench isolation regions 120 to expose the buried power rail 130.

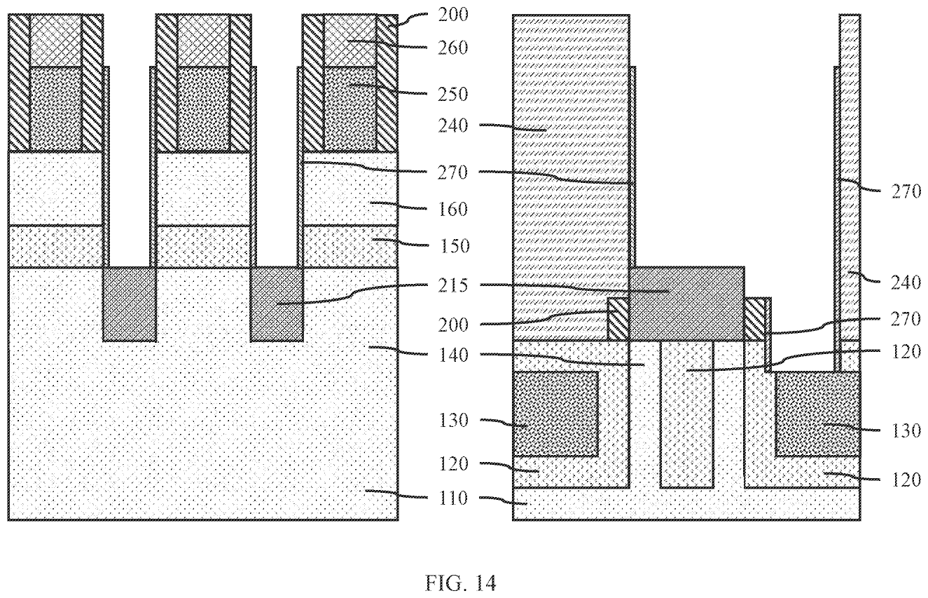

FIG. 14 illustrates perpendicular cross-sectional side views showing formation of a trench liner in the bottom contact trench, in accordance with an embodiment of the present invention.

In one or more embodiments, a trench liner 270 can be formed in the bottom contact trench 245, where the trench liner 270 can be formed by a conformal deposition (e.g., ALD, PEALD) of a trench liner layer, and portions of the trench liner layer removed from the horizontal surfaces using a selective, directional etch (e.g., RIE). The trench liner 270 can be formed on the sidewalls of the ILD layer 240 inside the bottom contact trench 245, and on the sidewalls of the sidewall spacers 200.

In various embodiments, the trench liner 270 can be a dielectric layer, such as SiO₂, SiN, SiBCN, SiC, SiCO, SiBCN, SiOCN, etc.

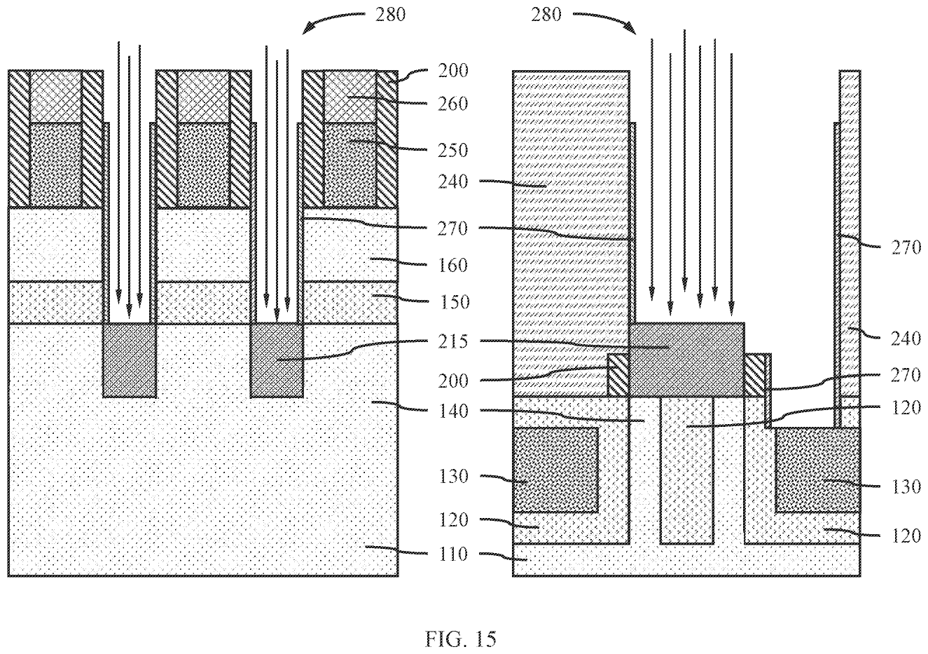

FIG. 15 illustrates perpendicular cross-sectional side views showing bottom source/drain implantation and pre-amorphization, in accordance with an embodiment of the present invention.

In one or more embodiments, the bottom source/drains 215 can be implanted with a dopant, such as Ge or Si for pre-amorphization, and dopants like B, Ga, P, As etc for PFET/NFET.

After implantation, a rapid thermal annealing will be followed for dopant activation or S/D re-crystallization.

By doing a proper pre-amorphization and dopant implantation over the bottom S/D epi, it will ensure a good contact formation between the silicide and S/D epi, and in one or more embodiments, the bottom source/drains 215 can have a contact resistance of about 5×10⁻¹⁰ Ω/cm² to about 5×10⁻⁹ Ω/cm². In conventional stacked FET approaches, such implantation can't be done to the bottom S/D epi, because the bottom S/D region is shadowed by the top S/D epi and implantation would not able to access the bottom S/D region.

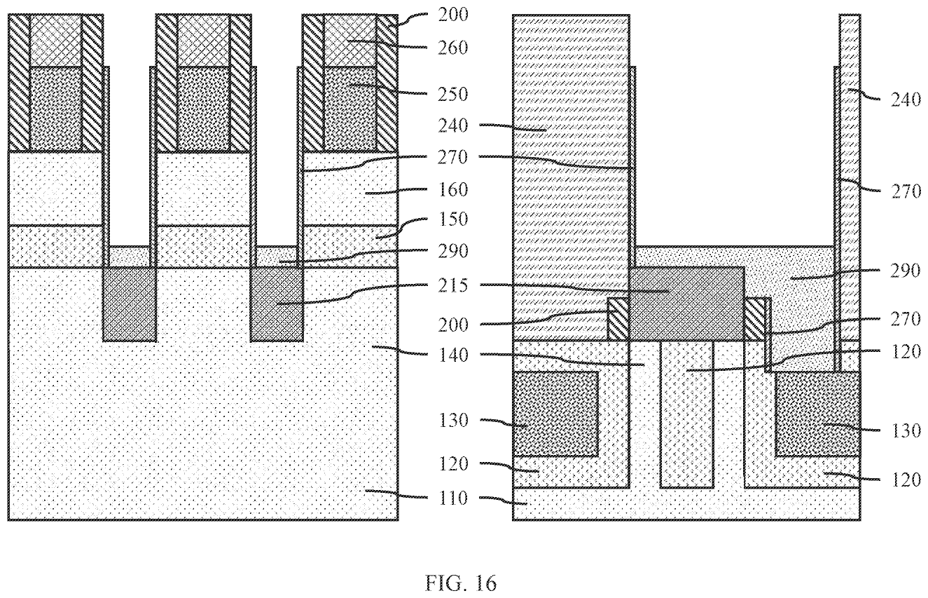

FIG. 16 illustrates perpendicular cross-sectional side views showing formation of a bottom contact in the bottom contact trench, in accordance with an embodiment of the present invention.

In one or more embodiments, a bottom contact 290 can be formed in the bottom contact trench 245, where the bottom contact 290 can be formed by a conformal deposition of a conductive material, and a selective isotropic etch-back used to reduce the bottom contact 290 to a predetermined height. The bottom contact 290 can form an electrical connection between the bottom source/drain 215 and the buried power rail 130. The bottom contact 290 can cover at least a portion of the bottom source/drain 215, sidewall spacer 200, and buried power rail 130. The top surface of the bottom contact 290 can be below the top surface of the insulating layer 150.

In various embodiments, the bottom contact 290 can be a metal, including, but not limited to, a silicide liner such as Ti, Ni, or NiPt, an adhesion metal liner, such as TiN or TaN, and a conductive metal layer, such as copper (Cu), tungsten (W), cobalt (Co), ruthenium (Ru), and combinations thereof.

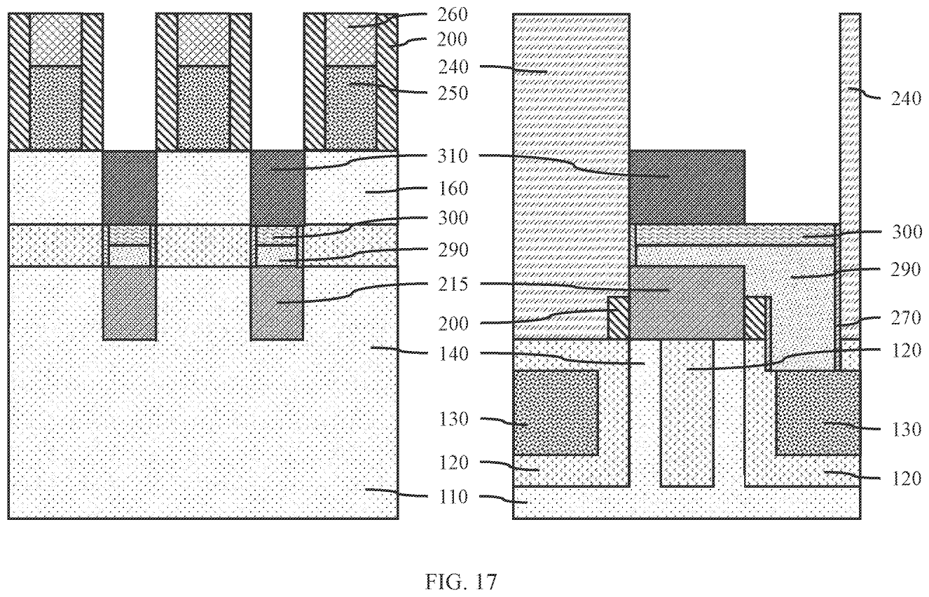

FIG. 17 illustrates perpendicular cross-sectional side views showing formation of a bottom contact cap in the bottom contact trench on the bottom contact, and a top source/drain formed on the top fin region and bottom contact cap, in accordance with an embodiment of the present invention.

In one or more embodiments, a bottom contact cap 300 can be formed on the bottom contact 290 in the bottom contact trench 245, where the bottom contact cap 300 can be formed by a dielectric deposition and etch-back. The bottom contact cap 300 can cover the bottom contact 290 and be adjacent to the trench liner 270. The top surface of the bottom contact cap 300 can be approximately coplanar (within the tolerances of the processes employed) with the top surface of the insulating layer 150.

After bottom contact cap 300 formation, in one or more embodiments, the exposed trench liner 270 is removed, and top source/drains 310 can be formed on the top fin region 160 and bottom contact cap 300, where the top source/drains 310 can be formed by lateral epitaxial growth from the side surfaces of the top fin regions 160. The top surface of the top source/drains 310 can be approximately coplanar with the top surface of the top fin regions 160. The top source/drains 310 can be over the bottom source/drains 215. The bottom contact cap 300 can electrically insulate the top source/drains 310 from the bottom contact 290 and bottom source/drains 215.

In various embodiments, the top source/drains 310 can be doped to be an n-type device or a p-type device, where the dopant type can be the opposite type from the bottom source/drains 215 to form a complimentary FET.

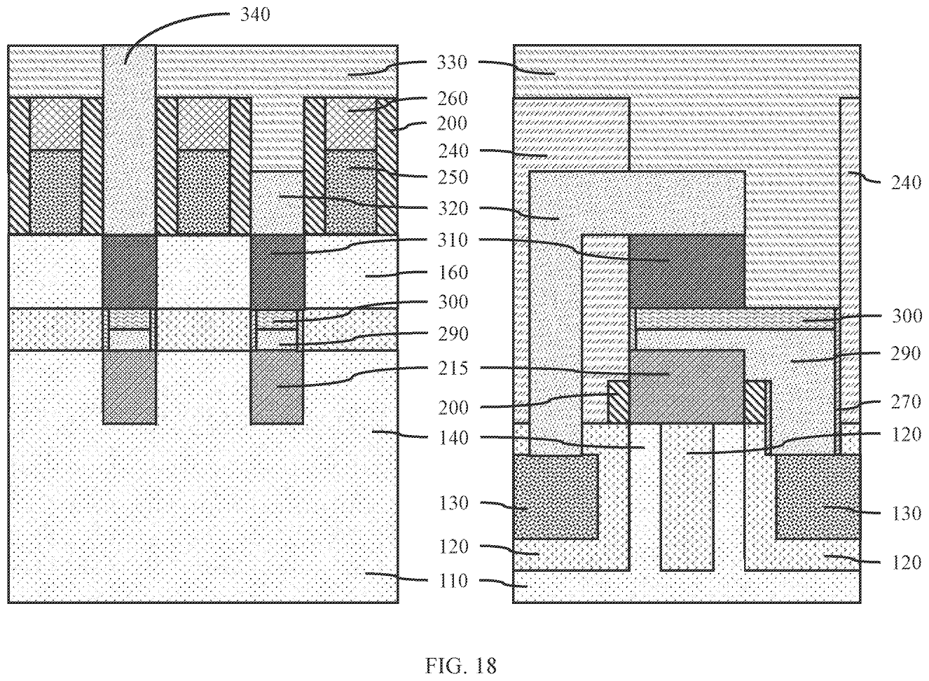

FIG. 18 illustrates perpendicular cross-sectional side views showing formation of a top source/drain contact between the top source/drain and a second buried power rail, and a signal contact in a cover layer, in accordance with an embodiment of the present invention.

In one or more embodiments, a top source/drain contact 320 can be formed between the top source/drain 310 and a second buried power rail 130. The top source/drain contact 320 can be formed using lithographic processes and etching to form a top source/drain contact trench, and fill the top source/drain contact trench with a conductive material by conformal deposition.

In various embodiments, the top source/drain contact 320 can be a metal, including, but not limited to, a silicide liner such as Ti, Ni, or NiPt, an adhesion metal liner, such as TiN or TaN, and a conductive metal layer, such as copper (Cu), tungsten (W), cobalt (Co), ruthenium (Ru), and combinations thereof.

In one or more embodiments, a cover layer 330 can be formed on the gate dielectric cap 260, sidewall spacers 200, top source/drain contact 320, top source/drain 310, and bottom contact cap 300.

In various embodiments, the cover layer 330 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

In one or more embodiments, a signal contact 340 can be formed in a cover layer 330, where the signal contact 340 can be in electrical contact with a top source/drain 310. The signal contact 340 can be formed by lithographic processes and a deposition of a conductive material. The signal contact 340 can provide an electrical connection for a signal out from the device.

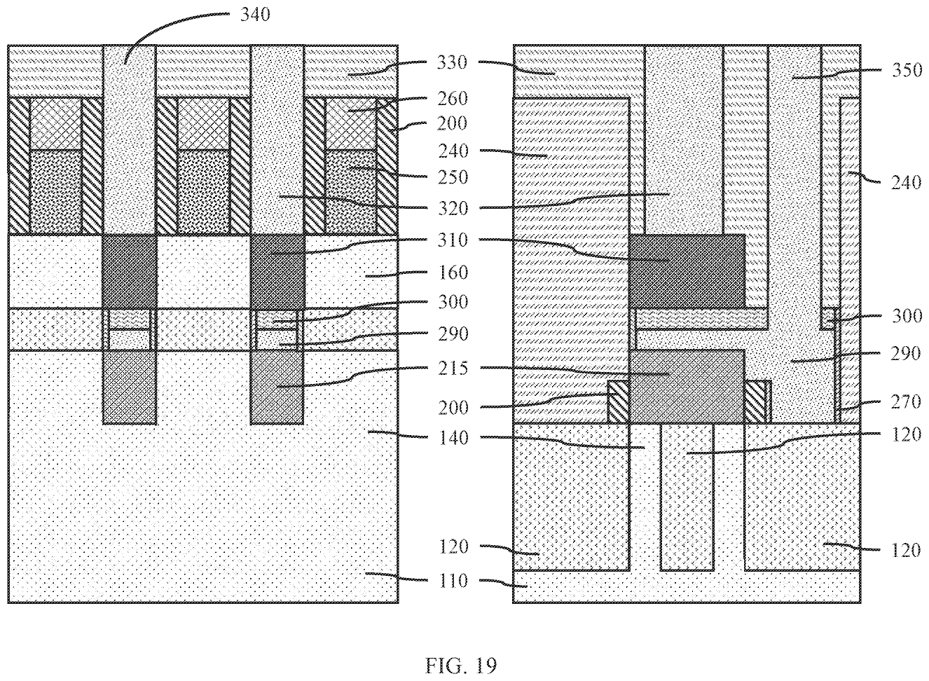

FIG. 19 illustrates perpendicular cross-sectional side views showing formation of a bottom source/drain contact and a top source/drain contact in a cover layer, in accordance with an embodiment of the present invention.

In one or more embodiments, a top source/drain contact 320 can be formed to the top source/drain 310 through the cover layer 330.

In one or more embodiments, a bottom source/drain contact 350 can be formed through the cover layer 330 to the bottom contact 290.

In various embodiments, a buried power rail 130 may not be formed in the shallow trench isolation region(s) 120, so the contacts are made to the top side and electrically connected to a BEOL.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Having described preferred embodiments of a device and method of fabricating the device (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device, comprising:
a top field effect device over a bottom field effect device;
a bottom contact electrically connecting a bottom source/drain of the bottom field effect device to a first buried power rail;
a bottom contact cap on the bottom contact; and
a trench liner on opposite sides of the bottom contact cap and the bottom contact.

2. The semiconductor device of claim 1, wherein the interface between the bottom source/drain and the bottom contact has a contact resistance of about 5×10⁻¹⁰ Ω/cm² to about 5×10⁻⁹ Ω/cm².

3. The semiconductor device of claim 1, further comprising a top source/drain contact electrically connecting a top source/drain of the top field effect device to a second buried power rail.

4. The semiconductor device of claim 1, wherein the top field effect device is a p-type field effect transistor (PFET) device and the bottom field effect device is an n-type field effect transistor device (NFET).

5. The semiconductor device of claim 1, wherein the top field effect device is an n-type field effect transistor (NFET) device and the bottom field effect device is a p-type field effect transistor device (PFET).

6. The semiconductor device of claim 1, further comprising a portion of a sidewall spacer separating the bottom contact from a substrate.

7. The semiconductor device of claim 1, wherein the bottom contact cap separates the bottom source/drain from a top source/drain.

8. The semiconductor device of claim 7, wherein the trench liner is on an interlayer dielectric (ILD) layer between the bottom source/drain and the top source/drain.

9. A semiconductor device, comprising:
a top field effect device having a top source/drain over a bottom field effect device having a bottom source/drain;
a bottom contact in electrical contact with the bottom source/drain of the bottom field effect device; and
a bottom contact cap on the bottom contact, wherein a portion of the bottom contact and a portion of the bottom contact cap separate the bottom source/drain from the top source/drain.

10. The semiconductor device of claim 9, further comprising a trench liner on opposite sides of the bottom contact cap and the bottom contact.

11. The semiconductor device of claim 10, further comprising a top source/drain contact in electrical contact with the top source/drain of the top field effect device.

12. The semiconductor device of claim 11, wherein the top source/drain contact electrically connects the top source/drain to a first buried power rail.

13. The semiconductor device of claim 12, wherein the bottom source/drain contact electrically connects the bottom source/drain to a second buried power rail.

14. The semiconductor device of claim 13, further comprising a portion of a sidewall spacer separating the bottom contact from a substrate.

15. A method of fabricating a semiconductor device, comprising:
forming a bottom source/drain on a bottom fin region;
implanting and pre-amorphization the bottom source/drain with a dopant;
forming a bottom contact on the bottom source/drain;
forming a bottom contact cap on the bottom contact; and
forming a top source/drain on the bottom contact cap and a top fin region.

16. The method of claim 15, further comprising forming a first buried power rail in a substrate, wherein the bottom contact is also on the first buried power rail, and electrically connects the bottom source/drain to the first buried power rail.

17. The method of claim 16, further comprising forming a top source/drain contact on the top source/drain.

18. The method of claim 17, further comprising forming a second buried power rail in the substrate, wherein the top source/drain contact is also on the second buried power rail, and electrically connects the top source/drain to the second buried power rail.

19. The method of claim 18, wherein the bottom contact cap separates the bottom source/drain from the top source/drain.

20. The method of claim 19, wherein the dopant implanted into the bottom source/drain is an n-type dopant.
